(19) United States
(12) Patent Application Publication
(10) Pub. No.: US 2012/0160542 A1
(43) Pub. Date: Jun. 28, 2012

(54) CROSSTALK REDUCTION ON MICROSTRIP ROUTING

(76) Inventors: Olufemi B. Oluwafemi, Hillsboro, OR (US); Xiaoning Ye, Portland, OR (US)

(21) Appl. No.: 12/976,551

(22) Filed: Dec. 22, 2010

(51) Int. Cl. H05K 1/02

(52) U.S. Cl. 174/250

(57) ABSTRACT

In some embodiments a plurality of differential pair traces include microstrip routing and a layer is formed over the plurality of differential pair traces. The layer formed over the plurality of differential pair traces is a thick solder mask, a dielectric layer, and/or a solder mask with a high dielectric constant. Other embodiments are described and claimed.

### RELATED APPLICATION

This application is related to U.S. patent application Ser. No. ______ entitled “DIFFERENTIAL SIGNAL CROSSTALK REDUCTION” to Xiaoning Ye and filed on even date herewith.

### TECHNICAL FIELD

The inventions generally relate to crosstalk reduction for microstrip routing.

### BACKGROUND

Microstrip routing is commonly used for trace routing on boards such as Printed Circuit Boards (PCBs). However, microstrip routing suffers a much greater amount of crosstalk as compared with stripline routing. This is due to the fact that there is more inductive coupling (which results in a positive crosstalk value) than capacitive coupling (which results in a negative crosstalk value) when using microstrip routing. Microstrip traces usually have a large far-end crosstalk (FEXT), which degrades the quality of the signal transmitted using the microstrip traces.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates a system according to some embodiments of the inventions.

### DETAILED DESCRIPTION

Some embodiments of the inventions relate to crosstalk reduction on microstrip routing.

In some embodiments a plurality of differential pair traces include microstrip routing and a layer is formed over the plurality of differential pair traces. The layer formed over the plurality of differential pair traces is a thick solder mask, a dielectric layer, and/or a solder mask with a high dielectric constant.

In some embodiments far-end crosstalk (FEXT) is reduced, and a smaller amount of real estate is required for routing on a board such as a Printed Circuit Board (PCB).

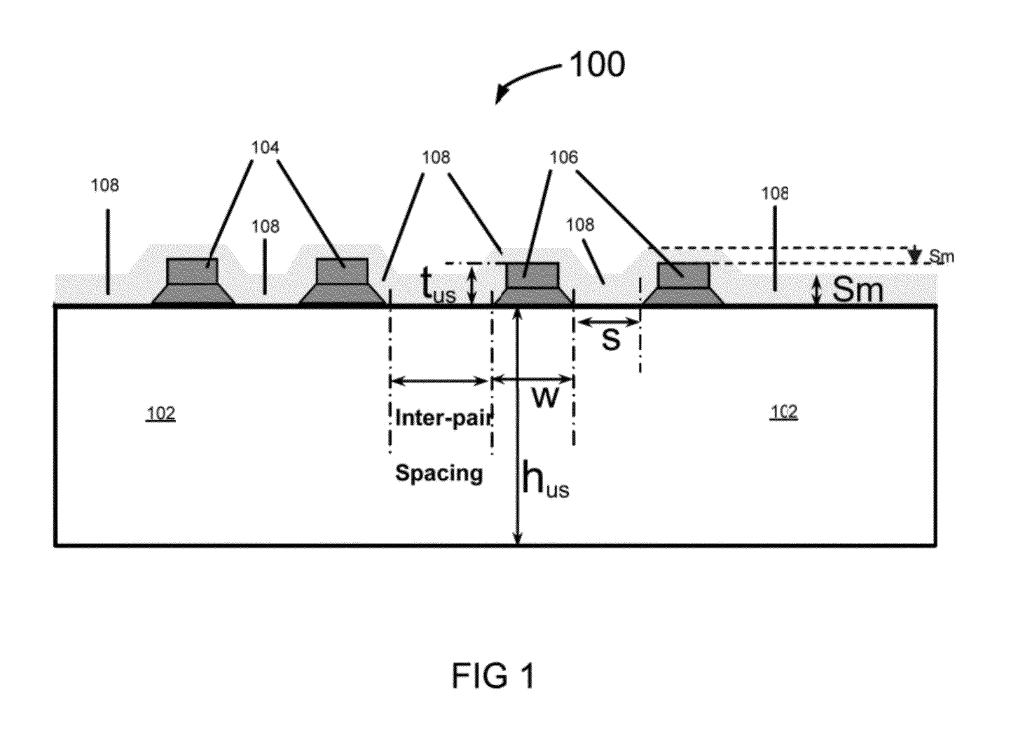

FIG. 1 illustrates a system 100 according to some embodiments. In some embodiments system 100 is included on a board and/or a PCB. In some embodiments system includes a dielectric (and/or dielectric layer and/or dielectric substrate) 102, a first differential signaling pair 104, a second differential signaling pair 106, and a solder mask 108.

In some embodiments, “s” in FIG. 1 illustrates an intra-pair spacing, “w” in FIG. 1 illustrates a trace width, “d” in FIG. 1 illustrates an inter-pair spacing, “hus” in FIG. 1 illustrates a dielectric height, “Sm” in FIG. 1 illustrates a solder mask height, and “tus” in FIG. 1 illustrates a trace and copper plating height.

In some embodiments, the first differential signaling pair 104 and/or the second differential signaling pair 106 are high speed differential signaling pairs. In some embodiments, the first differential signaling pair 104 and/or the second differential signaling pair 106 each include a trace and copper plating. In some embodiments, the first differential signaling pair 104 and/or the second differential signaling pair 106 are implemented using microstrip trace routing. As discussed above, microstrip traces usually have a far-end crosstalk (FEXT) that degrades signal quality. Microstrip routing is commonly used in PCB routing, although it suffers much greater crosstalk than that of stripline routing. This is due to the fact that microstrip routing results in more inductive coupling (which results in a positive crosstalk value) than capacitive coupling (which results in a negative crosstalk value). In some embodiments, the solder mask 108 height (Sm) is at least 0.8 mils higher than the trace and copper plating height of the first differential signal (that is, the thickness of the solder mask 108 is 0.8 mils or greater).

According to some embodiments, a solder mask such as solder mask 108 is intentionally thickened (for example, to 0.8 mils or more). In some embodiments a dielectric layer is included on top of the traces (for example, on top of the traces of differential signals 104 and/or 106). In some embodiments, a high dielectric constant is used in a solder mask (for example, in solder mask 108). In some embodiments a closer spacing is provided between the routing traces (for example between the traces of differential signals 104 and/or 106). These embodiments decrease the far end crosstalk (FEXT) that occurs in microstrip routing, while allowing for a closer spacing between routing traces, allowing for improved routing density. By providing an extra dielectric on top of the routing trace and/or closer spacing between the routing traces of the routing pair, capacitive coupling is increased, and inductive coupling is canceled out. This is an improvement in current solutions of the FEXT problem associated with microstrip routing, where extra spacing is used and real estate on the board is thereby limited. Such a solution is not always a viable solution since it causes real estate issues on the board. In some embodiments, on the other hand, spacing between microstrip routing signals is reduced, thereby increasing real estate on the board.

According to some embodiments, far-end crosstalk (FEXT) is reduced, thereby improving the signaling performance.

Solder mask 108 is placed on the board to keep parts from shorting out. In some embodiments, the solder mask 108 is intentionally made thicker. In some embodiments, the thickness Sm of the solder mask is 0.8 mil or more greater than the height of the trace (that is solder mask 108 extends a distance Sm of 0.8 mil or more higher than the height tus of the trace and copper plating of the differential signaling pairs such as differential signaling pairs 104 and/or 106 of FIG. 1). This is much thicker than the solder mask used in a typical PCB stackup, where the solder mask extends only about 0.3 mils higher than the height of the trace plus the copper plating (tus).

In some embodiments, where layer count is a concern, for example, signals are often routed on the surface layers as microstrip. This leads to space constraints because microstrip traces have previously needed to be spaced farther apart than stripline traces in order to reduce crosstalk effects. Thus, according to some embodiments, crosstalk is reduced and a reduction of interpair spacing for microstrip traces is implemented. Additionally, the signaling performance is improved due to the reduced crosstalk.

Based on observations by the present inventors, the crosstalk of a system such as system 100 of FIG. 1 with a solder mask 108 thickness Sm of 0.8 mils higher than the height tus of the trace plus the copper plating is reduced by as much as 40% compared with a solder mask thicknes (Sm) of 0.3 mils higher than the height (tus) of the trace plus the copper plating. The crosstalk of the 0.8 mil solder mask implementation is inverted relative to the 0.3 mil implementation for a 5 mil trace width (w), a 5 mil intra-pair spacing (s), and a 4 mil inter-pair spacing (d).

Similarly, the present inventors have observed that using a solder mask 108 height (Sm) of 0.8 mils above the trace and copper plating and using traces with an inter-pair spacing (d) of 4 mils, 5 mils, 6 mils or 7 mils results in a lower crosstalk than using the same solder mask 108 height (Sm) of 0.8 mils and an inter-pair spacing (d) of 14 mils. As such, according to some embodiments, more real estate is available on the board, allowing for more signals to be routed on platforms while significantly reducing crosstalk in systems using microstrip routing. As the inter-pair spacing (d) is changed from 4 mils to 14 mils, for example, inter-pair spacing (d) dominates the capacitive coupling effect, which results in a lower crosstalk for implementations using an inter-pair spacing (d) in the range of 4 mils to 7 mils. According to some embodiments, the combination of solder mask thickness and a small inter-pair spacing between differential pair signals helps to significantly reduce crosstalk and increase routing density on a board.

Although some embodiments have been described herein as being implemented in a particular manner, according to some embodiments these particular implementations may not be required.

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, the interfaces that transmit and/or receive signals, etc.), and others.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. An apparatus comprising:
a plurality of differential pair traces including microstrip routing; and
a layer formed over the plurality of differential pair traces, wherein the layer formed over the plurality of differential pair traces is a thick solder mask, a dielectric layer, and/or a solder mask with a high dielectric constant.

2. The apparatus of claim 1, wherein the thick solder mask is a solder mask with a thickness over the plurality of differential pair traces of 0.8 mils or greater.

3. The apparatus of claim 1, wherein an inter-pair spacing between two of the plurality of differential pair traces is in a range of 4 mils to 7 mils.

4. The apparatus of claim 2, wherein an inter-pair spacing between two of the plurality of differential pair traces is in a range of 4 mils to 7 mils.

5. The apparatus of claim 1, wherein an inter-pair spacing between two of the plurality of differential pair traces is approximately 4 mils.

6. The apparatus of claim 2, wherein an inter-pair spacing between two of the plurality of differential pair traces is approximately 4 mils.

7. The apparatus of claim 1, wherein a width of one or more of the differential pair traces is approximately 5 mils, an intra-pair spacing of one or more of the differential pair traces is 5 mils, and/or an inter-pair spacing between two or more of the differential pair traces is 4 mils.

8. The apparatus of claim 1, wherein the layer formed over the plurality of differential pair traces reduces crosstalk between the plurality of differential pair traces.

9. The apparatus of claim 1, wherein the layer formed over the plurality of differential pair traces reduces far-end crosstalk between the plurality of differential pair traces.

10. The apparatus of claim 1, wherein the layer formed over the plurality of differential pair traces increases capacitive coupling and cancels out inductive coupling.

11. The apparatus of claim 1, further comprising a dielectric layer, wherein the plurality of differential pair traces including microstrip routing are formed over the dielectric layer.

12. The apparatus of claim 1, wherein the apparatus is a Printed Circuit Board.

13. An apparatus comprising:
one or more traces including microstrip routing; and
a layer formed over the one or more traces, wherein the layer formed over the one or more traces is a thick solder mask, a dielectric layer, and/or a solder mask with a high dielectric constant.

14. The apparatus of claim 13, wherein the thick solder mask is a solder mask with a thickness over the one or more traces of 0.8 mils or greater.

15. The apparatus of claim 13, wherein a width of one or more of the differential pair traces is approximately 5 mils.

16. The apparatus of claim 13, wherein the layer formed over the one or more traces reduces crosstalk between two or more traces.

17. The apparatus of claim 13, wherein the layer formed over the one or more traces reduces far-end crosstalk between two or more traces.

18. The apparatus of claim 13, wherein the layer formed over the one or more traces increases capacitive coupling and cancels out inductive coupling.

19. The apparatus of claim 13, further comprising a dielectric layer, wherein the one or more traces including microstrip routing are formed over the dielectric layer.

20. The apparatus of claim 13, wherein the apparatus is a Printed Circuit Board.
